(19) United States
(12) Patent Application Publication
(10) Pub. No.: US 2026/0177618 A1
(43) Pub. Date: Jun. 25, 2026

(54) METHOD FOR DIAGNOSING A CIRCUIT BREAKER AND ASSOCIATED COMPUTER PROGRAM

(71) Applicant: Schneider Electric Industries SAS, Rueil Malmaison (FR)

(72) Inventors: David LANES, Saint Hilaire du Touvet (FR); Julien RAMEAU, Saint Hilaire du Touvet (FR); Amaud RIVALS, Herbeys (FR); Florent PERROT, Crolles (FR); Nicolas LAYDEVANT, Grenoble (FR); Benoit HAGE, Saint Jean de Moirans (FR); Augustin CATHIGNOL, Grenoble (FR); Fabrice D'EUSTACHIO, Vaulnaveys-le-bas (FR); Elena STOLYAROVA, Fontanil-Cornillon (FR)

(21) Appl. No.: 19/416,901

(22) Filed: Dec. 11, 2025

(30) Foreign Application Priority Data
Dec. 19, 2024 (FR) FR2414657

(51) Int. Cl. G01R 31/327; G06T 7/00

(52) U.S. Cl. CPC G01R 31/327; G06T 7/0002; G06T 2207/20081; G06T 2207/20084

(57) ABSTRACT

The present invention relates to a method (200) for diagnosing a circuit breaker comprising at least one pole, each pole comprising an electrical contact configured to switch between a closed position and an open position.

The method comprises:
for each pole of the circuit breaker, capturing (208A, 208B) an image of the electrical contact of the pole at least once;
for each pole of the circuit breaker, determining (218A, 218B) at least once a state of pole health among at least two states by means of an artificial-intelligence algorithm, the artificial-intelligence algorithm receiving as input at least one image of the pole and delivering as output the state of pole health;
determining (220A, 220B) a state of health of the circuit breaker among at least two states, depending on the state of health of each pole; and
rendering (222, 224) the state of health of the circuit breaker.

### BACKGROUND

The present invention relates to a method for diagnosing a circuit breaker. It also relates to an associated computer program.

Circuit breakers are essential safety devices allowing a current in an electrical installation to be interrupted in the event of an electrical fault. It is therefore important to monitor the state of health of the circuit breakers present in an electrical installation, in order to ensure that they are able to keep the electrical installation safe and to replace them if required.

The lifespan of a circuit breaker is, in particular, determined by a number of opening/closing cycles and by the current switched. If the number of past cycles and the current switched is known, it is therefore possible to estimate the remaining lifespan of the circuit breaker.

However, in real-life situations, information on the number of past cycles and the current switched is only available for a very limited number of circuit breakers, i.e. those equipped with an advanced electronic tripping unit comprising an accessory for counting the number of times the circuit breaker has opened/closed and for measuring the current switched. In all other cases, no method currently allows an operator to effectively determine the state of health of a circuit breaker within an electrical installation, or therefore to deduce whether a replacement is required for safety functions to continue to be performed.

### SUMMARY

The aim of the invention is thus to provide a method for diagnosing a circuit breaker allowing the state of health of a circuit breaker, which need not be equipped with an advanced electronic tripping unit, to be determined in situ, i.e. without requiring the circuit breaker to be removed from the electrical installation beforehand.

To this end, one subject of the invention is a method for diagnosing a circuit breaker comprising at least one pole, each pole comprising an electrical contact configured to switch between a closed position and an open position, wherein the method comprises:
for each pole of the circuit breaker, capturing an image of the electrical contact of the pole at least once;
for each pole of the circuit breaker, determining at least once a state of pole health among at least two states by means of an artificial-intelligence algorithm, the artificial-intelligence algorithm receiving as input at least one image of the pole and delivering as output the state of pole health;
determining a state of health of the circuit breaker among at least two states, depending on the state of health of each pole; and
rendering the state of health of the circuit breaker.

By virtue of the invention, the state of health of the circuit breaker is estimated in situ from an image captured directly on the electrical installation. In particular, the method, through use of artificial intelligence, allows an analysis of the contacts of the circuit breaker to be carried out that would be difficult or even impossible for a non-expert without detailed knowledge of the structure of the circuit breaker or knowledge of the aging conditions of the contact pads to carry out. By virtue of the method of the invention, it is possible to decide whether or not it is necessary to replace the circuit breaker to continue to ensure the safety of the electrical installation. Furthermore, capturing an image avoids the need to disassemble the circuit breaker, this substantially improving serviceability and saving a substantial amount of time.

According to other advantageous aspects of the invention, the diagnosing method comprises one or more of the following features, implemented alone or in any technically possible combination:
for each pole of the circuit breaker:
   the image of the electrical contact is captured by means of an endoscopic probe; and
   the method comprises, prior to the image capture, inserting the endoscopic probe into the circuit breaker, into proximity with a mobile contact pad belonging to the electrical contact;
for each pole of the circuit breaker:
   the one or more image captures are performed while the electrical contact of the pole is in open position; and
   the artificial-intelligence algorithm used to determine at least once the state of pole health is a classifying algorithm that receives as input the one or more images captured while the electrical contact is in open position and that delivers as output a pole state among a critical state, a non-compliant state, a compliant state, and a good state;
for each pole of the circuit breaker:
   the one or more image captures are performed while the electrical contact of the pole is in closed position; and
   the artificial-intelligence algorithm used to determine at least once the state of pole health is an anomaly-detecting algorithm that receives as input the one or more images captured while the electrical contact is in closed position and that delivers as output a pole state among a repulsed state and a non-repulsed state;
the state of health of the circuit breaker is determined to be either a valid state or an invalid state, the invalid state being determined if, for at least one pole:
   the state of pole health predicted by the classifying algorithm is the critical state or non-compliant state, or
   the state of pole health predicted by the anomaly-detecting algorithm is the repulsed state;
the valid state being determined otherwise;
images of the electrical contacts in closed position are captured at least once and the anomaly-detecting algorithm determines at least once if and only if the state of health of each pole predicted by the classifying algorithm is the good state or compliant state;
the method further comprises, for each image captured, at least one action of reconfiguring the image, which action is selected from among converting the image to grayscale, normalizing a contrast of the image and resizing the image;
each artificial-intelligence algorithm is trained in an initialization phase prior to the method, each initialization phase comprising:
   for each training circuit breaker among a set of training circuit breakers and for each pole of the training circuit breaker, capturing at least one image of the contact of the pole;
   for at least one obtained image, at least one action of randomly transforming the image; and
   training of the artificial-intelligence algorithm on at least one set of training images among the images;
the phase of initialization of the classifying algorithm further comprises:
   for each image, an expert assigning to the pole a first actual state of health among an actual critical state, an actual non-compliant state, an actual compliant state, and an actual good state; and
   dividing the obtained images into a first training set, a first validation set and a first test set, each first set containing at least one image belonging to each of the actual critical state, the actual non-compliant state, the actual compliant state and the actual good state, the training comprising training, validating and testing the classifying algorithm on the first training set, the first validation set and the first test set, respectively;
the phase of initialization of the anomaly-detecting algorithm further comprises:
   for each image, an expert assigning to the pole a second actual state of health among an actual repulsed state and an actual non-repulsed state; and
   dividing the obtained images into a second training set, a second validation set and a second test set, the second training set solely containing images the second actual state of health of which is the actual repulsed state and the second validation and test sets containing at least one image belonging to each state among the actual repulsed state and the actual non-repulsed state, the training comprising training, validating and testing the anomaly-detecting algorithm on the second training set, the second validation set and the second test set, respectively;
the action of randomly transforming the image comprises at least one action among randomly modifying a contrast of the image, randomly modifying a brightness of the image, randomly rotating the image, and randomly shifting the image horizontally or vertically.

The invention also relates to a computer program comprising software instructions that, when they are executed by a computer, implement a diagnosing method such as defined above.

The invention will become more clearly apparent on reading the following description, which is given solely by way of non-limiting example, and with reference to the drawings, in which:

### BRIEF DESCRIPTION OF DRAWINGS

FIG. 1 shows a perspective view of a device allowing a method according to the invention to be implemented;

FIG. 2 is a cross-sectional schematic of one part of a circuit breaker and of one part of the device of FIG. 1;

FIG. 3 SHOWS A LONGITUDINAL CROSS SECTION OF THE DEVICE OF FIGURE 1;

FIGS. 4A and 4B show a perspective view of a guide belonging to the device of FIG. 1 from two distinct viewing angles;

FIGS. 5A to 5C show a perspective view of a spacer, a first spacer ring and a fourth spacer ring belonging to the device of FIG. 1;

FIGS. 6A to 6C show a perspective view and a cross-sectional view of a second spacer ring and a perspective view of a third spacer ring belonging to the device of FIG. 1;

FIG. 7 shows a side view of the device of FIG. 1 in the released position;

FIG. 8 is a flowchart of an initialization phase according to the invention;

FIG. 9 is a flowchart of a diagnosing method according to the invention.

### DETAILED DESCRIPTION

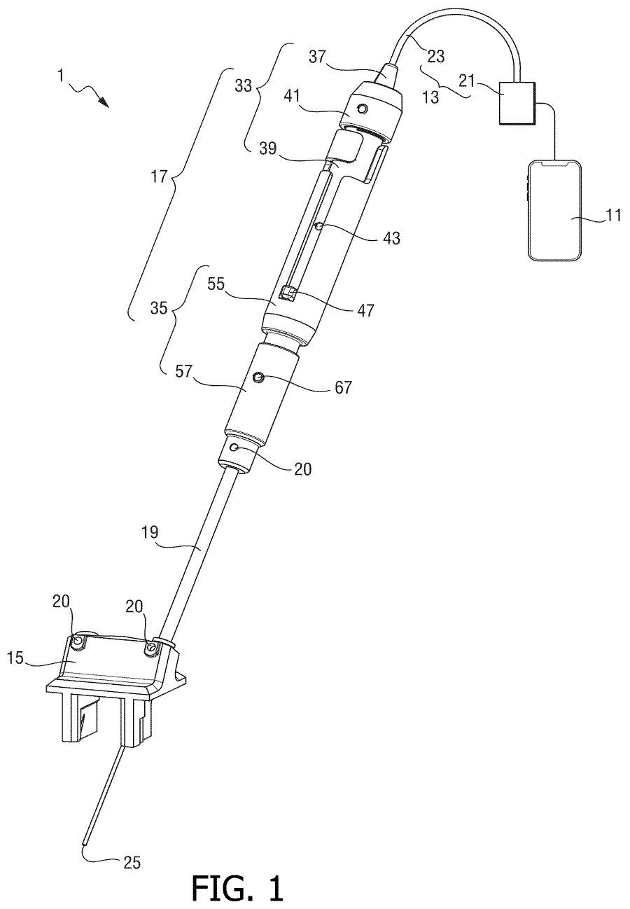

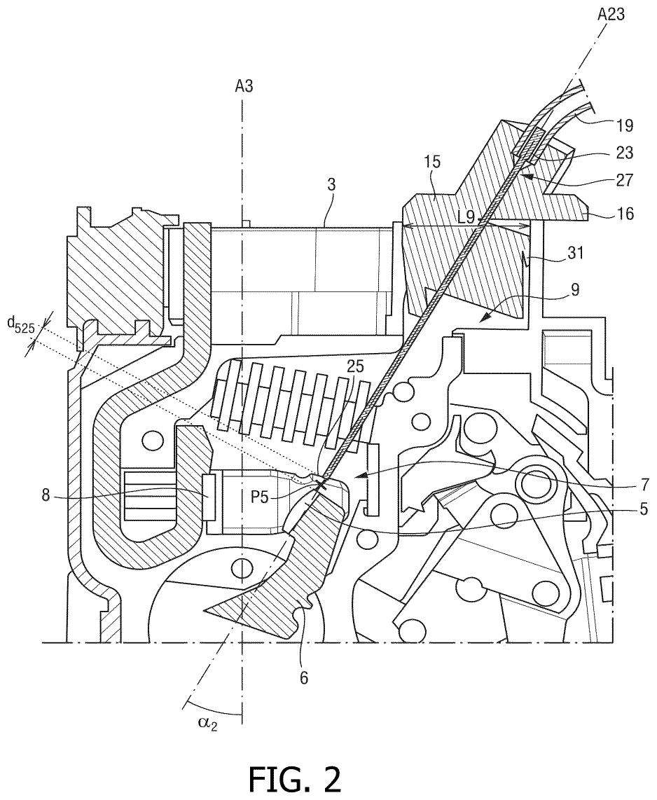

FIG. 1 shows a device 1 for capturing an image of a contact of a circuit breaker 3, the circuit breaker being shown only partially in FIG. 2.

The circuit breaker 3 is for example a molded case circuit breaker (MCCB). Its function is to detect an electrical fault occurring in an electrical installation (not shown) and to interrupt a current flowing through the electrical installation in the event of a fault. The circuit breaker 3 comprises at least one pole, generally three poles corresponding to three phases for a three-phase electrical installation, or indeed four poles corresponding to three phases and a neutral for a four-pole electrical installation. The structure of one pole of the circuit breaker 3 is partially visible in the cross-sectional view of FIG. 2. In particular, each pole comprises an electrical contact configured to switch between a closed position and an open position. Each electrical contact comprises a fixed part bearing a fixed contact pad 8 and a mobile part 6 carrying a mobile contact pad 5. The fixed and mobile contact pads 8, 5 allow a flow of current between the fixed part and mobile part to be initiated or interrupted, depending on an open or closed position of the mobile part 6. The cross-sectional plane of FIG. 2 allows one pole, with its mobile contact pad 5, to be seen, the other poles being similar.

During normal operation of the circuit breaker 3, when the electrical contact of a pole is in closed position, the circuit breaker 3 lets electrical current flow through the phase or neutral corresponding to the pole. Conversely, when the electrical contact is in open position, the circuit breaker 3 prevents current from flowing through the phase or neutral corresponding to the pole.

Each pole is advantageously confined in a separate chamber to the other poles. For each pole, the chamber defines a volume 7 that communicates with the exterior of the circuit breaker 3 via an exhaust chamber 9.

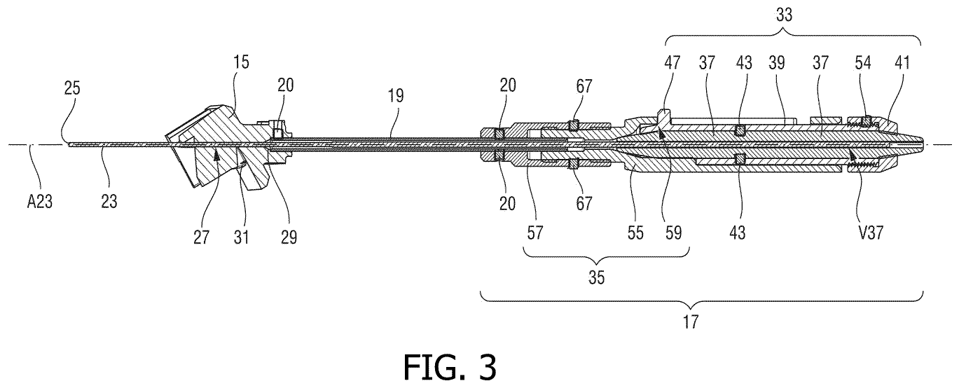

The imaging device 1, shown in perspective in FIG. 1 and in cross section in FIGS. 2 and 3, is configured to capture images of the electrical contacts of the circuit breaker 3. The device 1 is further connected to an external device 11 configured to implement a method for diagnosing the circuit breaker 3 as detailed below.

The imaging device 1 comprises an endoscopic probe 13, a guide 15 and a securing member 17. Advantageously, the imaging device 1 further comprises a tube 19.

The endoscopic probe 13 comprises a probe body 21 and an optical fiber 23. The endoscopic probe 13 is configured to capture images of elements surrounding a distal end 25 of the optical fiber 23.

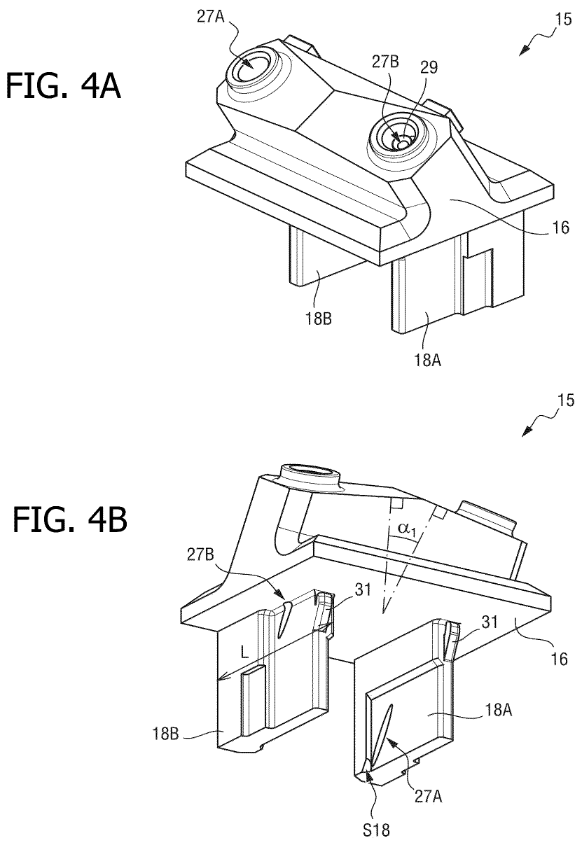

The guide 15 is configured to penetrate at least partially into the exhaust chamber 9 of the pole comprising the electrical contact of which it is desired to capture an image, as shown in FIG. 2. To this end, the guide 15 is a part the geometry of which is complementary to a shape of the exhaust chamber 9. The guide 15 is shown in greater detail in FIGS. 4A-B from two different viewing angles, corresponding to inserts A and B.

The guide 15 comprises at least one rectilinear cavity 27 configured to receive the optical fiber 23 and to guide the optical fiber 23 to a point P5 in proximity to the contact pad 5. In particular, the guide 15 is configured to guide the optical fiber 23 through the exhaust chamber 9, the optical fiber 23 then being guided, by mechanical parts belonging to the circuit breaker 3, into proximity with the contact pad 5 in the volume 7. Thus, the guide 15 allows the contacts of the circuit breaker 3 to be imaged in situ within the electrical installation, without needing to dismantle the circuit breaker 3 beforehand. The image of a contact of the circuit breaker 3 advantageously comprises the mobile contact pad 5, flanges positioned on either side of the mobile contact pad 5 and a spark guard.

The rectilinear shape of the cavity 27 makes it possible not to twist the optical fiber 23, limiting the risks of damaging the optical fiber 23. Furthermore, the diameter of the cavity 27 advantageously provides a clearance of the order of 0.1 mm with respect to the outside diameter of the optical fiber 23, this allowing easy insertion of the optical fiber 23 while ensuring good retention of the optical fiber 23 and a relatively low optical dispersion.

As may be seen in FIGS. 3 and 4A-B, the rectilinear cavity 27 comprises a mouth chamfer 29, facilitating insertion of the optical fiber 23 into the cavity 27. The chamfer 29 is positioned on a side of the guide 15 that is located opposite the distal end 25 of the optical fiber 23 when the optical fiber 23 is inserted in the cavity 27.

In the example shown in the figures, the guide 15 comprises two cavities 27A and 27B that make between them a non-zero angle α₁, so as to guide the optical fiber 23 to the same point P5 in proximity with the mobile contact pad 5 whichever cavity the optical fiber 23 is inserted into. In other words, axial extensions of the two cavities 27A and 27B converge to the point P5. Thus, when in the cavities 27A and 27B the optical fiber makes it possible to view the same contact, from two viewing angles.

Advantageously, the guide 15 comprises at least one flexible tab 31 allowing a width L of the guide 15 to be adapted to a width L9 of the exhaust chamber 9, as clearly shown in FIG. 2. This feature allows the guide 15 to be held fast and allows for tolerances in respect of the variation in the width L9 of the exhaust chambers 9 from one pole to another and from one circuit breaker 3 to another.

Advantageously, the guide 15 comprises a base 16 and two lugs 18A and 18B that extend parallel to each other from the base 16. The guide 15 is one piece.

Advantageously, the cavities 27A and 27B pass through the base 16. Each cavity 27A or 27B first extends through the outer side of the lug through which it passes, as shown for the lug 18B of insert B) of FIG. 4B, and then through the inner side of the lug through which it passes, as shown for the lug 18A of insert B) of FIG. 4B. Each of the cavities 27A and 27B advantageously opens onto the inner side of the lug 18A or 18B through which it passes.

The cross-sectional plane of FIG. 2 passes through the lug 18B and the cavity 27 shown in this figure corresponds to the cavity 27B shown in FIGS. 4A-B.

Preferably, each lug 18A or 18B is configured so as not to hinder passage of the optical fiber 23, nor to damage it as it progresses toward the point P5. Thus, the side of the lug 18A shown in insert B) of FIG. 4B comprises a cutout that defines a surface S18 for guiding the optical fiber 23 as it exits from the cavity 27A.

The securing member 17 is configured to hold the optical fiber 23 inserted in the guide 15 longitudinally in such a way as to define a distance d525 between the distal end 25 of the optical fiber 23 and the mobile contact pad 5, and an angle α₂ between a longitudinal axis A3 of the circuit breaker 3 and a longitudinal axis A23 of the optical fiber 23. This feature allows images to be captured with greater reproducibility by means of the device 1.

The securing member 17 is advantageously divided into a proximal securing element 33 and a distal securing element 35. The proximal securing element 33 is securely fastened to the endoscopic probe 13 while the distal securing element 35 is securely fastened to the guide 15, through the tube 19, as explained below.

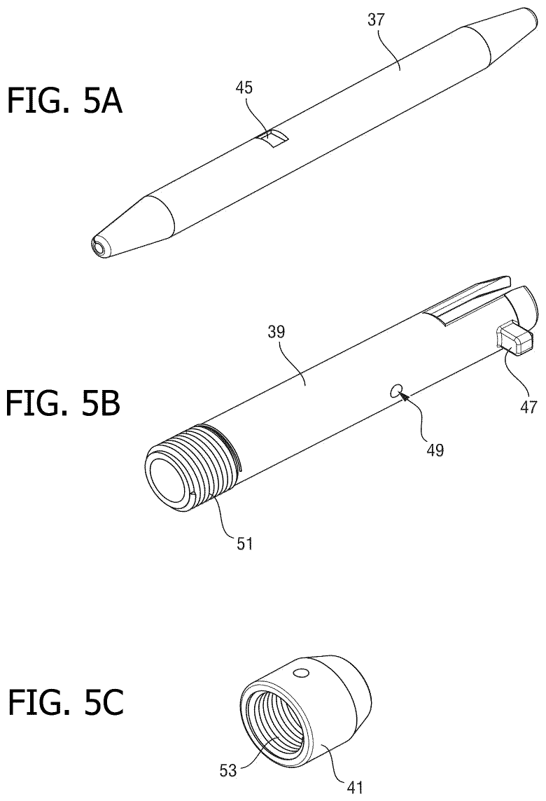

In the example illustrated, the proximal securing element 33 comprises a spacer 37, a first spacer ring 39 and a cap 41. These various components are shown individually in inserts A), B) and C) of FIGS. 5A-C.

The spacer 37 is configured to partially encircle the optical fiber 23 and to be securely fastened to the optical fiber 23. To this end, at least one clamping screw 43, and advantageously two clamping screws 43 as shown in FIG. 3, grip the spacer 37 so as to locally decrease a diameter of an internal volume V37 of the spacer 37 serving to accommodate the optical fiber 23 and thus fasten the spacer 37 to the optical fiber 23. In the example illustrated, the two clamping screws 43 also serve to securely fasten the spacer 37 to the first spacer ring 39. The spacer 37 advantageously comprises at least one notch 45 for partially receiving the or each clamping screw 43.

The first spacer ring 39 at least partially encircles the spacer 37 and is securely fastened to the spacer 37. As shown in insert B) of FIG. 5B, the first spacer ring 39 comprises a male stop 47, and two holes 49 allowing the clamping screws 43 to pass. Advantageously, the first spacer ring 39 further comprises an external first thread 51 allowing it to interact with the cap 41.

The cap 41, shown in insert C) of FIG. 5C, advantageously comprises an internal second thread or tapping 53 configured to interact with the external first thread 51. The cap 41 is advantageously securely fastened to the first spacer ring 29 by means of a connecting screw 54. The cap 41 makes it easier for an operator to grasp the securing member 17 and to hold the spacer 37 in the first spacer ring 39.

As shown in FIGS. 1 and 3, the distal securing element 35 is joined to the guide by way of the tube 19, configured to receive the optical fiber 23. In particular, the tube 19 is attached to the guide 15 and to the distal securing element 35 by means of mounting screws 20. The mounting screws 20 are received by respective holes in the guide 15 and in the distal securing element 35.

Thus, the optical fiber 23 passes through the proximal securing element 33, the distal securing element 35, the tube 19 and then the guide 15.

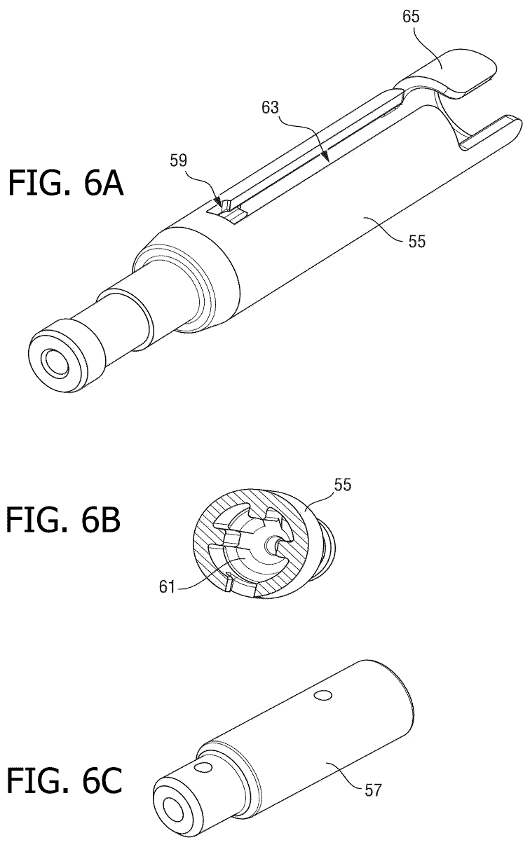

The distal securing element 35 comprises a second spacer ring 55 and, optionally, a complementary third spacer ring 57. These elements are shown individually in FIGS. 6A-C.

When the securing member 17 is in its mounted configuration, the second spacer ring 55 at least partially encircles the first spacer ring 39. The second spacer ring 55 is able to translate with respect to the first spacer ring 39 along the longitudinal axis A23 of the optical fiber 23 and to rotate with respect to the first spacer ring 39 about the longitudinal axis A23 of the optical fiber 23. The second spacer ring 55 comprises a female stop 59 configured to interact with the male stop 47. Inserting the male stop 47 into the female stop 59 makes it possible to securely fasten the second spacer ring 55, and therefore the distal securing element 35, to the first spacer ring 39, and therefore to the proximal securing element 33, in the manner of a bayonet mount. In other words, inserting the male stop 47 into the female stop 59 makes it possible to block translation and rotation between the optical fiber 23 and guide 15, with respect to the longitudinal axis A23 of the optical fiber 23. Since the guide 15 is held by the circuit breaker 3 when the guide 15 is inserted into the exhaust chamber 9, inserting the male stop 47 into the female stop 59 makes it possible to fix the position of the optical fiber 23 with respect to the circuit breaker 3, and in particular with respect to the mobile contact pad 5. It will be understood therefore that the securing member 17 allows images of the electrical contacts to be captured with greater repeatability by means of the endoscopic probe 13.

Advantageously, the second spacer ring 55 further comprises a mouth chamfer 61 facilitating insertion of the optical fiber 23 into the second spacer ring 55, as may be seen in the cross-sectional view of insert B) of FIG. 6B.

In the example illustrated, the second spacer ring 55 further comprises a release groove 63 parallel to the longitudinal axis A23 of the optical fiber 23. The release groove 63 is configured to interact with the male stop 47 and to guide, via the male stop 47, the first spacer ring 39 translationally with respect to the second spacer ring 55, from the female stop 59, along the longitudinal axis A23 of the optical fiber 23, until the optical fiber 23 is completely outside the circuit breaker 3.

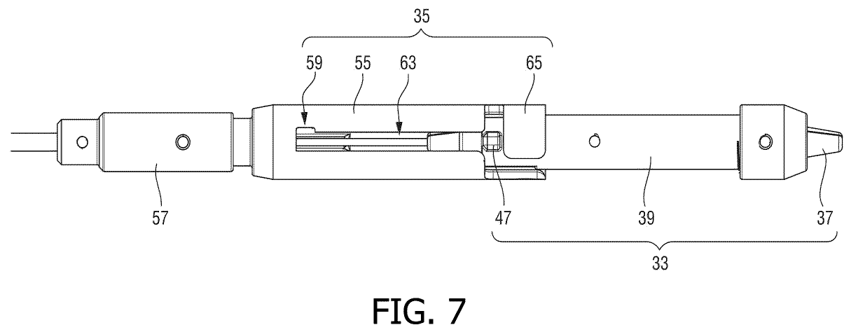

Advantageously, the second spacer ring 55 further comprises a release stop 65 blocking translation of the first spacer ring 39 with respect to the second spacer ring 55 when the optical fiber 23 is completely outside the circuit breaker 3. The device 1 is then said to be in the released position. The released position is shown in FIG. 7. The released position allows an operator to remove the guide 15 from the circuit breaker 3 without damaging the optical fiber 23, which is generally fragile and represents most of the cost of the device 1.

In the example illustrated, a rotation of the proximal securing element 33 with respect to the distal securing element 35, while the device 1 is in the released position, allows the proximal securing element 33 to be removed from the distal securing element 35. Thus, the guide 15 and the endoscopic probe 13 are again independent.

The third spacer ring 57 at least partially encircles the second spacer ring 55. The third spacer ring 57 is able to be translated along the longitudinal axis A23 of the optical fiber 23, with respect to the second spacer ring 55, and to be rotated about the longitudinal axis A23 of the optical fiber 23, with respect to the second spacer ring 55. The third spacer ring 57 is securely fastened to the second spacer ring 55 by means of micro-adjustment screws 67. Thus, rotation and translation between the second spacer ring 55 and third spacer ring 57 when the micro-adjustment screws are loosened makes it possible to finely adjust the position of the optical fiber 23 with respect to the circuit breaker 3, after the male stop 47 has been inserted into the female stop 59.

The various aforementioned components of the imaging device 1, apart from the endoscopic probe 13 and the tube 19, are advantageously 3D printed from a resin. More generally, the device 1 is at least partly 3D printed from a resin. This manufacturing process requires all the dimensions of these components to be greater than or equal to 0.3 mm.

The external device 11 is connected to the probe body 21 by a wired or wireless link, so as to receive the images captured by the endoscopic probe 13.

The external device 11 is advantageously a smartphone or a tablet on which an application configured to implement the method for diagnosing the circuit breaker 3 is installed.

More generally, the external device 11 comprises an electronic circuit designed to manipulate and/or convert data represented by electronic or physical quantities in registers and/or in memories into other similar data corresponding to physical data in the memories of registers or other types of display device, transmission device or memory device.

By way of specific examples, the external device 11 may take the form of a programmable logic component, such as a field-programmable gate array (FPGA), or of a dedicated integrated circuit, such as an application-specific integrated circuit (ASIC).

As a variant, when the diagnosing method is implemented via one or more pieces of software, i.e. via a computer program, i.e. what is also called a computer program product, it is further capable of being recorded on a computer-readable medium (not shown). The computer-readable medium is, for example, a medium capable of storing electronic instructions and of being connected to a bus of a computer system. By way of an example, the readable medium is an optical disc, a magneto-optical disc, a ROM, a RAM, any type of non-volatile memory (for example, FLASH or NVRAM) or a magnetic board. A computer program comprising software instructions is then stored on the readable medium.

The diagnosing method consists in determining a state of health of the circuit breaker 3 based on images of the electrical contacts of the circuit breaker 3 captured using the device 1 described above and by means of at least one artificial-intelligence algorithm. Each artificial-intelligence algorithm receives as input an image of an electrical contact of one pole and delivers as output a state of pole health. More precisely, each artificial-intelligence algorithm delivers a probability for each state of pole health. Each probability is between 0 and a normalized maximum probability, for example 1, 10 or 100. The sum of the probabilities obtained for each state of health is then equal to the normalized maximum probability. The highest probability gives the predicted state of pole health. The probability of the predicted state of pole health provides a level of confidence in said predicted state of health.

Advantageously, the diagnosing method employs two distinct artificial-intelligence algorithms, one called the classifying algorithm and one called the anomaly-detecting algorithm.

The classifying algorithm is advantageously a supervised classifying algorithm known to those skilled in the art. By way of example, the classifying algorithm is a neural network, for example a convolutional neural network, a recurrent neural network or a transformer. The classifying algorithm receives as input at least one image of an electrical contact in open position and delivers as output a state of the corresponding pole among a critical state, a non-compliant state, a compliant state and a good state, and the associated confidence level between 0 and the normalized maximum probability. As a variant, the predicted pole state is merely one among a good state of health and a non-compliant state of health.

The anomaly-detecting algorithm is advantageously a semi-supervised learning algorithm known to those skilled in the art. By way of example, the anomaly-detecting algorithm is a combination of neural networks. The anomaly-detecting algorithm receives as input at least one image of an electrical contact in closed position and delivers as output a pole state among a repulsed state and a non-repulsed state.

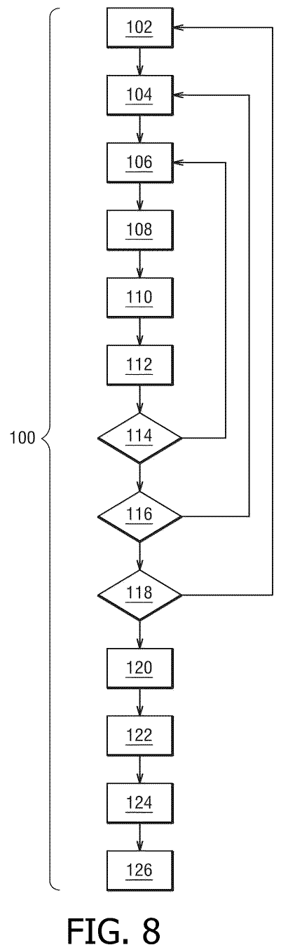

Each artificial-intelligence algorithm is trained, prior to the diagnosing method, in an initialization phase 100 shown in FIG. 8 and described below.

The initialization phase 100 involves a set of training circuit breakers. The training circuit breakers are advantageously of the same type as the circuit breaker 3 to be diagnosed. In order to be able to apply the diagnosing method to various types of circuit breakers 3, the training phases 100 are advantageously repeated for various circuit breakers, delivering one trained artificial-intelligence algorithm for each type of circuit breaker.

Each initialization phase 100 comprises capturing 108 at least one image of an electrical contact of each pole of each training circuit breaker, an action of randomly transforming 122 the image, and training 126 the artificial-intelligence algorithm on at least one set of images containing the image.

In the example illustrated in FIG. 8, the initialization phase 100 begins with opening or closing 102 the electrical contact of the training circuit breaker to be photographed. In the phase 100 of initialization of the supervised classifying algorithm, this step 102 is a step of opening the electrical contact. In the phase 100 of initialization of the semi-supervised anomaly-detecting algorithm, this step 102 is a step of closing the electrical contact.

The initialization phase 100 then comprises inserting 104 the guide 15 into the exhaust chamber 9 of the pole of the training circuit breaker comprising the electrical contact to be photographed, then a phase of inserting 106 the optical fiber 23 into the guide 15. The position of the optical fiber 23 with respect to the circuit breaker is then fixed by inserting the male stop 47 into the female stop 59 and then tightening the micro-adjustment screws 67. As explained above, the distal end 25 of the optical fiber 23 is then in proximity with the contact pad 5, at point P5.

In the capturing step 108, an image of the electrical contact and of its environment is captured by the endoscopic probe 13 and then transmitted to the external device 11. The image advantageously contains the moving contact comprising the mobile contact pad 5, flanges positioned on either side of the mobile contact pad 5 and a spark guard.

The optical fiber 23 and the guide 15 are then removed from the training circuit breaker in a withdrawal phase 110. The withdrawal phase advantageously comprises withdrawing the optical fiber 23 from the guide 15 until the device 1 is in the released position, then withdrawing the guide 15 from the circuit breaker 3.

Next, the initialization phase comprises an expert assigning 112 an actual state of pole health, through an analysis of the appearance of the contact pad 5 and of its environment based on the image transmitted to the external device 11, and on conditions of use of the circuit breaker 3. In the phase 100 of initialization of the supervised classifying algorithm, the actual state of pole health is selected by the expert from an actual critical state, an actual non-compliant state, an actual compliant state and an actual good state. As a variant, the actual state of pole health is selected solely from an actual good state and an actual non-compliant state. In the phase 100 of initialization of the anomaly-detecting algorithm, the actual state of pole health is selected by the expert from an actual repulsed state and an actual non-repulsed state.

As a variant (not shown), the assigning step 112 takes place before the withdrawing step 110.

The steps of opening/closing 102, inserting 104 and 106, capturing 108, withdrawing 110 and assigning 112 are repeated as many times as required to generate a set of training images of sufficient size to make the artificial-intelligence algorithm reliable, 20 or 50 times for example.

In the example illustrated in FIG. 8, a first testing step 114 consists in checking whether each side of an electrical contact has been photographed, and if not, in repeating the procedure starting with insertion 106 of the optical fiber into the guide 15 in order to photograph the other side of the electrical contact. A second testing step 116 consists in checking whether each pole of the training circuit breaker has been photographed, and if not, in repeating the procedure starting with insertion 104 of the guide 15 into the exhaust chamber 9 in order to photograph another pole. A third testing step 118 consists in checking whether each training circuit breaker of the set of training circuit breakers, corresponding to the number of times required, has been photographed, and if not, in repeating the procedure starting with the opening/closing step 102 in order to photograph another training circuit breaker. Thus, the initialization phase illustrated in FIG. 8 makes it possible to capture one image for each side of each electrical contact of each training circuit breaker.

The images thus obtained are then divided, in a dividing step 120, into a training set, a test set and a validation set.

In the phase 100 of initialization of the supervised classifying algorithm, the images are divided into a first training set, a first validation set and a first test set. Each first set contains at least one image belonging to each among the actual critical state, the actual non-compliant state, the actual compliant state, and the actual good state. Advantageously, each state is represented in equal proportions in each of the first sets. This division makes it possible to implement supervised training known to those skilled in the art.

In the phase 100 of initialization of the anomaly-detecting algorithm, the images are divided into a second training set, a second validation set and a second test set. The second training set contains solely images the second actual state of health of which is the actual repulsed state, and the second validation and test sets contain at least one image belonging to each among the actual repulsed state and the actual non-repulsed state. This division makes it possible to implement semi-supervised training known to those skilled in the art.

In the randomly transforming step 122, at least one random transformation is applied to at least one image. The random transformation for example comprises randomly modifying a contrast of the image, randomly modifying a brightness of the image, randomly rotating the image, and/or randomly shifting the image horizontally or vertically. Advantageously, each image receives a random transformation probability. When the transformation probability is zero, no transformation is applied. When the transformation probability is non-zero, a combination of one or more transformations is applied. This random transformation makes it possible to reproduce a variability in the images captured during the diagnosing method. In other words, the random transformation allows the artificial-intelligence algorithms to be made less sensitive to variations in imaging conditions.

The initialization phase 100 then comprises reconfiguring 124 the images for the artificial-intelligence algorithm in question. The reconfiguring step 124 for example comprises converting the image to grayscale, normalizing a contrast of the image and resizing the image. The reconfiguring step 124 makes it possible to make the images more exploitable by the artificial-intelligence algorithm.

Lastly, the training step 126 comprises training, validating and testing the artificial-intelligence algorithm on the training set, validation set and test set, respectively.

At the end of the initialization phase 100, the artificial-intelligence algorithm in question has been trained and is capable of predicting the state of health of a pole of the circuit breaker 3 from a photo of the contact of the pole.

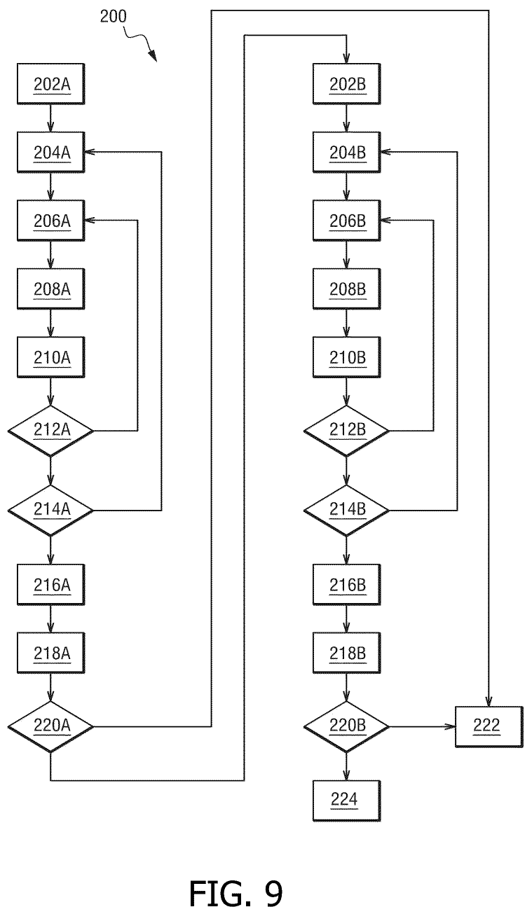

The trained artificial-intelligence algorithm is integrated into the external device 11, so that the diagnosing method 200, which is described below with reference to FIG. 9, may be implemented by the external device 11.

The diagnosing method 200 comprises capturing 206A or 206B an image of the electrical contact of each pole of the circuit breaker 3 at least once, determining 218A or 218B the state of health of each pole at least once, determining 220A and 220B the state of health of the circuit breaker 3, and rendering 222 and 224 the state of health of the circuit breaker 3.

In the example illustrated in FIG. 9, the diagnosing method 200 comprises, in succession, predicting the state of the poles of the circuit breaker 3 by means of the supervised classifying algorithm, and then by means of the anomaly-detecting algorithm. The state of health of the circuit breaker 3 is then predicted depending on the predictions of the two algorithms, as described below.

In the example shown in FIG. 9, the diagnosing method 200 comprises a step 202A of opening the contact of the circuit breaker 3, a step 204A of inserting the guide 15 into the exhaust chamber 9, a step 206A of inserting the optical fiber 23 into the guide 15, a step 208A of capturing an image of the electrical contact and a step 210A of withdrawing the optical fiber 23 and guide 15.

The method then comprises testing steps 212A and 214A that are similar to the testing steps 114 and 116 of the initialization phase 100. The testing steps 212A and 214A make it possible to repeat the previous steps until an image is captured on each side of each electrical contact of the circuit breaker 3.

Next, the diagnosing method 200 comprises a reconfiguring step 216A, similar to the reconfiguring step 124 of the initialization phase 100, allowing the images of the poles of the circuit breaker 3 to be reconfigured for the supervised classifying algorithm.

Next, the state of pole health is predicted by the supervised classifying algorithm in the determining step 218A. As explained above, the state of pole health predicted by the supervised classifying algorithm is a critical state, a non-compliant state, a compliant state or a good state.

The state of each pole is then taken into account in the step 220A of determining the state of health of the circuit breaker. The predicted state of health of the circuit breaker is advantageously either a valid state or an invalid state.

In particular, if the state of health of at least one pole predicted by the classifying algorithm is the critical state or the non-compliant state, then the state predicted for the circuit breaker 3 is the invalid state. The step 222 of rendering the invalid circuit-breaker state is then executed. The rendition for example takes the form of a display on a screen of the external device 11, allowing an operator to be informed that the circuit breaker 3 is invalid and must be replaced to continue to ensure the safety of the electrical installation.

Conversely, if the classifying algorithm does not predict the critical state or non-compliant state for any pole, then the state of pole health is predicted by the anomaly-detecting algorithm in order to determine whether or not repulsion is present, with a view to making a conclusion as to the state of health of the circuit breaker 3. Thus, images of the electrical contact in closed position are captured and the anomaly-detecting algorithm determines a plurality of times if and only if the state of health of each pole predicted by the classifying algorithm is the good state or compliant state. If such is the case, steps 202B to 220B are executed.

### Steps 202b to 220b Are Similar to Steps 202a to 220a Except for the differences mentioned below.

Unlike step 202A, which is a step of opening the electrical contacts, step 202B is a step of closing the electrical contacts of the circuit breaker 3.

The reconfiguring step 216B reconfigures the images for the anomaly-detecting algorithm.

The step 218B of determining the state of health of each pole is carried out by means of the anomaly-detecting algorithm. The predicted state of health is then the repulsed state or non-repulsed state. If the state of health of at least one pole of the circuit breaker 3 is the repulsed state, the circuit breaker is declared invalid and the step 222 of rendering the invalid state of health of the circuit breaker is executed. Conversely, if the state of health of all the poles is the non-repulsed state, then the circuit breaker is declared valid and the step 224 of rendering the valid state of the circuit breaker is executed.

In summary, the invalid state of the circuit breaker is determined if, for at least one pole, the state of pole health predicted by the classifying algorithm is the critical state or non-compliant state, or if the state of pole health predicted by the anomaly-detecting algorithm is the repulsed state; the valid state being determined otherwise.

Thus, at the end of the diagnosing method 200, the state of health of the circuit breaker 3 installed in the electrical installation is known and rendered by the external device 11. This knowledge makes it possible to take suitable measures to replace and/or carry out maintenance on the circuit breaker 3, in order to ensure essential functions in respect of the electrical safety of the electrical installation are performed.

Any feature described above in respect of one example or variant may also be implemented in the other examples or variants described above, insofar as technically feasible.

1. A method for diagnosing a circuit breaker comprising at least one pole, each pole comprising an electrical contact configured to switch between a closed position and an open position, wherein the method comprises:
for each pole of the circuit breaker, capturing an image of the electrical contact of the pole at least once;
for each pole of the circuit breaker, determining at least once a state of pole health among at least two states by means of an artificial-intelligence algorithm, the artificial-intelligence algorithm receiving as input at least one image of the pole and delivering as output the state of pole health;
determining a state of health of the circuit breaker among at least two states, depending on the state of health of each pole; and
rendering the state of health of the circuit breaker.

2. The method as claimed in claim 1, wherein, for each pole of the circuit breaker:
the image of the electrical contact is captured by means of an endoscopic probe; and
the method comprises, prior to the image capture inserting the endoscopic probe into the circuit breaker, into proximity with a mobile contact pad belonging to the electrical contact.

3. The method as claimed in claim 1, wherein, for each pole of the circuit breaker:
the one or more image captures are performed while the electrical contact of the pole is in open position; and
the artificial-intelligence algorithm used to determine at least once the state of pole health is a classifying algorithm that receives as input the one or more images captured while the electrical contact is in open position and that delivers as output a pole state among a critical state, a non-compliant state, a compliant state, and a good state.

4. The method as claimed in claim 1, wherein, for each pole of the circuit breaker:
the one or more image captures are performed while the electrical contact of the pole is in closed position; and
the artificial-intelligence algorithm used to determine at least once the state of pole health is an anomaly-detecting algorithm that receives as input the one or more images captured while the electrical contact is in closed position and that delivers as output a pole state among a repulsed state and a non-repulsed state.

5. The method as claimed in claim 3, wherein the state of health of the circuit breaker is determined to be either a valid state or an invalid state, the invalid state being determined if, for at least one pole:
the state of pole health predicted by the classifying algorithm is the critical state or non-compliant state, or
the state of pole health predicted by the anomaly-detecting algorithm is the repulsed state;
the valid state being determined otherwise.

6. The method as claimed in claim 5, wherein images of the electrical contacts in closed position are captured at least once and the anomaly-detecting algorithm determines at least once if and only if the state of health of each pole predicted by the classifying algorithm is the good state or compliant state.

7. The method as claimed in claim 1, further comprising, for each image captured, at least one action of reconfiguring the image, which action is selected from among converting the image to grayscale, normalizing a contrast of the image and resizing the image.

8. The method as claimed in claim 1, wherein each artificial-intelligence algorithm is trained in an initialization phase prior to the method, each initialization phase comprising:
for each training circuit breaker among a set of training circuit breakers and for each pole of the training circuit breaker, capturing at least one image of the contact of the pole;
for at least one obtained image, at least one action of randomly transforming the image; and
training of the artificial-intelligence algorithm on at least one set of training images among the images.

9. The method as claimed in claim 3, wherein the phase of initialization of the classifying algorithm further comprises:
for each image, an expert assigning to the pole a first actual state of health among an actual critical state, an actual non-compliant state, an actual compliant state, and an actual good state; and
dividing the obtained images into a first training set, a first validation set and a first test set, each first set containing at least one image belonging to each of the actual critical state, the actual non-compliant state, the actual compliant state and the actual good state, the training comprising training, validating and testing the classifying algorithm on the first training set, the first validation set and the first test set, respectively.

10. The method as claimed in claim 4, wherein the phase of initialization of the anomaly-detecting algorithm further comprises:
for each image, an expert assigning to the pole a second actual state of health among an actual repulsed state and an actual non-repulsed state; and
dividing the obtained images into a second training set, a second validation set and a second test set, the second training set solely containing images the second actual state of health of which is the actual repulsed state and the second validation and test sets containing at least one image belonging to each state among the actual repulsed state and the actual non-repulsed state, the training comprising training, validating and testing the anomaly-detecting algorithm on the second training set, the second validation set and the second test set, respectively.

11. The method as claimed in claim 8, wherein the action of randomly transforming the image comprises at least one action among randomly modifying a contrast of the image, randomly modifying a brightness of the image, randomly rotating the image, and randomly shifting the image horizontally or vertically.

12. A computer program comprising software instructions that, when they are executed by a computer, implement a method as claimed in claim 1.

13. The method as claimed in claim 4, wherein the state of health of the circuit breaker is determined to be either a valid state or an invalid state, the invalid state being determined if, for at least one pole:
the state of pole health predicted by the classifying algorithm is
the critical state or non-compliant state, or
the state of pole health predicted by the anomaly-detecting algorithm is the repulsed state;
the valid state being determined otherwise.

14. The method as claimed in claim 13, wherein images of the electrical contacts in closed position are captured at least once and the anomaly-detecting algorithm determines at least once if and only if the state of health of each pole predicted by the classifying algorithm is the good state or compliant state.

15. The method as claimed in claim 8, wherein the phase of initialization of the classifying algorithm further comprises:
for each image, an expert assigning to the pole a first actual state of health among an actual critical state, an actual non-compliant state, an actual compliant state, and an actual good state; and
dividing the obtained images into a first training set, a first validation set and a first test set, each first set containing at least one image belonging to each of the actual critical state, the actual non-compliant state, the actual compliant state and the actual good state, the training comprising training, validating and testing the classifying algorithm on the first training set, the first validation set and the first test set, respectively.

16. The method as claimed in claim 8, wherein the phase of initialization of the anomaly-detecting algorithm further comprises:
for each image, an expert assigning to the pole a second actual state of health among an actual repulsed state and an actual non-repulsed state; and
dividing the obtained images into a second training set, a second validation set and a second test set, the second training set solely containing images the second actual state of health of which is the actual repulsed state and the second validation and test sets containing at least one image belonging to each state among the actual repulsed state and the actual non-repulsed state, the training comprising training, validating and testing the anomaly-detecting algorithm on the second training set, the second validation set and the second test set, respectively.

17. The method as claimed in claim 9, wherein the action of randomly transforming the image comprises at least one action among randomly modifying a contrast of the image, randomly modifying a brightness of the image, randomly rotating the image, and randomly shifting the image horizontally or vertically.

18. The method as claimed in claim 10, wherein the action of randomly transforming the image comprises at least one action among randomly modifying a contrast of the image, randomly modifying a brightness of the image, randomly rotating the image, and randomly shifting the image horizontally or vertically.
